(19) United States
(12) Patent Application Publication
(10) Pub. No.: US 2004/0071298 A1
(43) Pub. Date: Apr. 15, 2004

(54) Stereo speaker

(76) Inventor: Shyh-Dar Geeng, Hsin-Tien City (TW)

Correspondence Address: J.C. Patents, Inc., 4 Venture, Suite 250, Irvine, CA, 92618, US

(21) Appl. No.: 10/637,933

(22) Filed: Aug. 8, 2003

(30) Foreign Application Priority Data
Oct. 9, 2002 (TW) 91216062

(51) Int. Cl. H04R 1/02; H05K 5/00; H04R 9/06

(52) U.S. Cl. 381/89; 381/335; 381/352; 381/337; 181/155

(57) ABSTRACT

The stereo speaker includes at least one speaker and a sonic reflector. The speaker has a sound output opening where the sonic reflector is set. The sonic reflector reflects the sonic waves created by the speaker in the direction substantially perpendicular to the direction in which the sonic waves are generated from the speaker. The reflected sonic waves are circularly scattered from the stereo speaker.

### CROSS-REFERENCE TO RELATED APPLICATION

This application claims the priority benefit of Taiwan application serial no. 91216062, filed Oct. 9, 2002.

### BACKGROUND OF THE INVENTION

1. Field of the Invention

The invention relates in general to a stereo speaker. More particularly, the invention relates to a stereo speaker creating sound circularly.

2. Description of the Related Art

Upon a high-quality life demanded in the society, electric appliances are popularly allocated in home, for example, audio-visual instrument. The audio-visual instrument includes a surround audio implement constructed from an amplifier and multiple speakers for outputting sound. Accompanying with an image-output implement, such as TV, projector or plasma TV, and a data access device, such as CD player, VCD player, DVD player, video cassette player or audio cassette player, a home theater is substantially composed.

FIG. 1 is a schematic view showing a sound output of a conventional speaker. The speaker 10 has sound output channels 12, 14 scattering sonic waves in a fan shape 16, so the output of the sonic waves created by the speaker 10 is limited. Therefore, a wrap-around effect is created only in the region where the fan shapes scattered from all speakers are overlapped. In order to attain the surroundings with a high sound quality, the position and the facing direction of the speakers should be designed by a trained musician. No matter how many speakers are set, only in the condition that all of the speakers face a user, the wrap-around effect can be attained. As a result, the allocation for speakers is complicated and the region where a user can comfortably enjoy is limited.

Nowadays, the audio-visual instrument is popularized. Even there are many personal computers which the sound output is performed in multi-way type, an excellent performance effect can be performed when a user is running a multi-media program. The installation for the speakers is a problem for a computer user. Moreover, the effect of allocating the speakers by oneself is inferior to the professional audiovisual design, thereby the effect of the speakers cannot be completely performed.

### SUMMARY OF THE INVENTION

It is an objective according to the present invention to provide a stereo speaker. The sound created by the stereo speaker can be circularly scattered. Therefore, the speakers can be easily installed.

To achieve the foregoing and other objectives, the present invention provides a stereo speaker. The stereo speaker includes at least one speaker and a sonic reflector. The speaker has a sound output opening where the sonic reflector is set. The sonic reflector reflects the sonic waves created by the speaker in the direction substantially perpendicular to the direction in which the sonic waves are generated from the speaker. The reflected sonic waves are circularly scattered from the stereo speaker.

According to an embodiment of the present invention, the sonic reflector has a conical shape. The tip of the sonic reflector points towards the center of the sound output opening of the speaker. A frame connects the speaker and the sonic reflector such that the speaker is spaced from the sonic reflector in a determined distance. The speaker has a cylinder shape and is allocated over a pedestal.

There are two sets of stereo speakers oppositely assembled for improving output power. Each of the speakers has a sound output opening positioned face to face. There are two sonic reflectors facing to the two sound output openings, respectively. The sonic reflectors can reflect the sonic waves created by the speakers and the reflected sonic waves are circularly scattered from the stereo speaker.

The stereo speaker has a sonic reflector with a conical shape, whereby the sonic waves can be circularly scattered from the stereo speaker. As a result, the stereo speaker is installed without attending to the direction thereof and thereby it can be easily set to attain the surroundings with a high sound quality.

Both the foregoing general description and the following detailed description are exemplary and explanatory only and are not restrictive of the invention, as claimed. It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view showing a sound output of a conventional speaker.

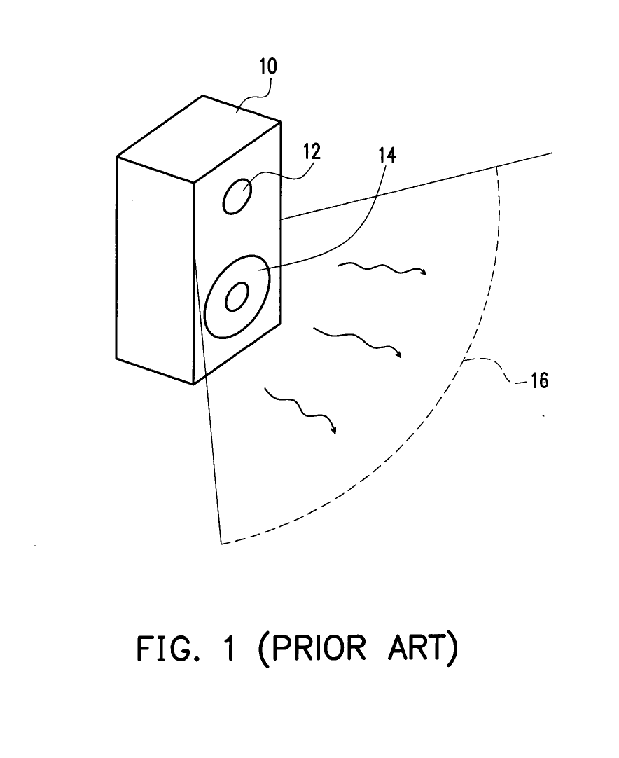

FIG. 2 is a perspective view showing a stereo speaker according to a first embodiment of the present invention.

FIG. 3 is a perspective view showing a stereo speaker according to a second embodiment of the present invention.

FIG. 4 is a perspective view showing a stereo speaker according to a third embodiment of the present invention.

### DESCRIPTION OF THE PREFERRED EMBODIMENTS

First Embodiment

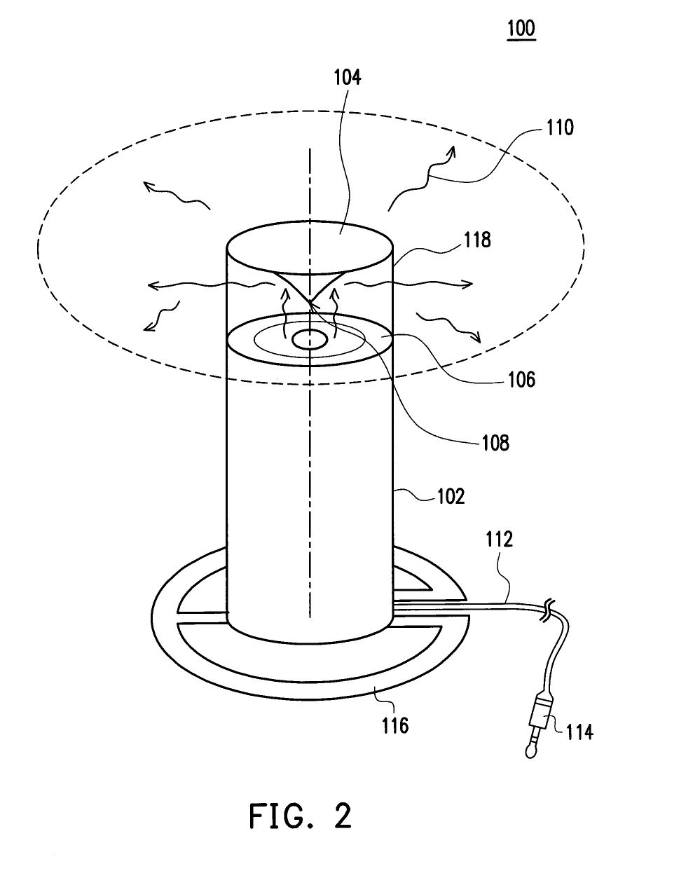

FIG. 2 is a perspective view showing a stereo speaker according to a first embodiment of the present invention. As shown in FIG. 2, the stereo speaker 100 is mainly constructed from a speaker 102 and a sonic reflector 104. The speaker 102 has a sound output opening 106 where the sonic reflector 104 is set. The sonic reflector 104 has a conical shape and the tip 108 of the sonic reflector 104 points towards the center of the sound output opening 106 of the speaker 102. The material of the sonic reflector 104 is metal, for example. The sonic reflector 104 has a curved surface. The sonic waves 110 can be reflected by the sonic reflector 104 in the direction substantially perpendicular to the direction in which the sonic waves 110 are generated from the speaker 102. The reflected sonic waves 110 are circularly scattered from the stereo speaker 100. Therefore, no matter where a user is, the user can hear the sound created from the stereo speaker 100 under a good condition. The sonic reflector 104 is allocated over the sound output opening 106 by a frame 118 such that the sound output opening 106 is spaced from the sonic reflector 104 in a determined distance in merit for reflecting the sonic waves 110.

For comfortable appearance, signal lines 112 extend from the bottom of the speaker 102 and are connected with a signal source, such as amplifier, disc player, video cassette player or computer, through a plug 114. If the speaker 102 is connected with a power source, a power line (not shown) can extend from the bottom of the speaker 102 and is connected with a power source through a plug. The stereo speaker 100 is provided with a pedestal 116 that is connected with the bottom portion of the speaker 102, so the stereo speaker 100 can be firmly laid.

Second Embodiment

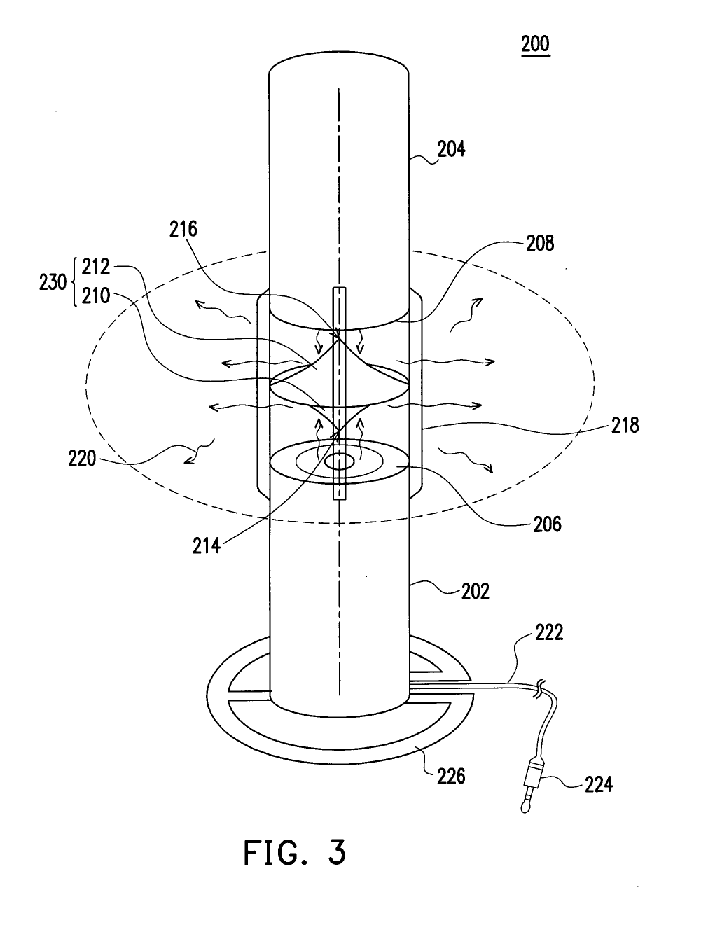

FIG. 3 is a perspective view showing a stereo speaker according to a second embodiment of the present invention. For improving output power, the stereo speaker in accordance with the present invention is not limited to be constructed from a single speaker. As shown in FIG. 3, the stereo speaker 200 is mainly constructed from two speakers 202, 204 and a sonic reflection unit 230. Each of the speakers 202, 204 has a sound output opening 206, 208 positioned face to face. The sonic reflection unit 230 is allocated between the sound output openings 206, 208. The sonic reflection unit 230 is constructed from two sonic reflectors 210, 212. Each of the sonic reflectors 210, 212 has a conical shape, the tips 214, 216 of the sonic reflectors 210, 212 pointing in the opposite direction and towards the center of the sound output openings 206, 208 of the speakers 202, 204, respectively. The material of the sonic reflectors 210, 212 is metal, for example. Each of the sonic reflectors 210, 212 has a curved surface. The sonic waves 220 can be reflected by the sonic reflectors 210, 212 in the direction substantially perpendicular to the direction in which the sonic waves 220 are generated from the speakers 202, 204. The reflected sonic waves 220 are circularly scattered from the stereo speaker 200. Therefore, no matter where a user is, the user can hear the sound created from the stereo speaker 200 under a good condition. A frame 218 connects the speakers 202, 204 and separates the speakers 202, 204 in a determined distance. The frame 218 fixes the sonic reflection unit 230 between the sound output openings 206, 208.

Signal lines 222 extend from the bottom of the speaker 202 and are connected with a signal source, such as amplifier, disc player, video cassette player or computer, through a plug 224. If the speaker 202 is connected with a power source, a power line (not shown) can extend from the bottom of the speaker 202 and is connected with a power source through a plug. The stereo speaker 200 is provided with a pedestal 226 that is connected with the bottom portion of the lower speaker 202, so the stereo speaker 200 can be firmly laid.

Third Embodiment

In the above embodiment, the speaker has a cylinder shape. However, the stereo speaker in accordance with the present invention is not limited to the above embodiment. In practice, the profile of the speaker can be designed in any desired shape, but, preferably, the cross-sectional shape of the sound output opening is center-symmetric in merit for scattering sonic waves. Besides, in the above embodiment, every speaker has only one vibrating plate. However, the stereo speaker in accordance with the present invention is not limited to the above embodiment. Also, a speaker has multiple vibrating plates.

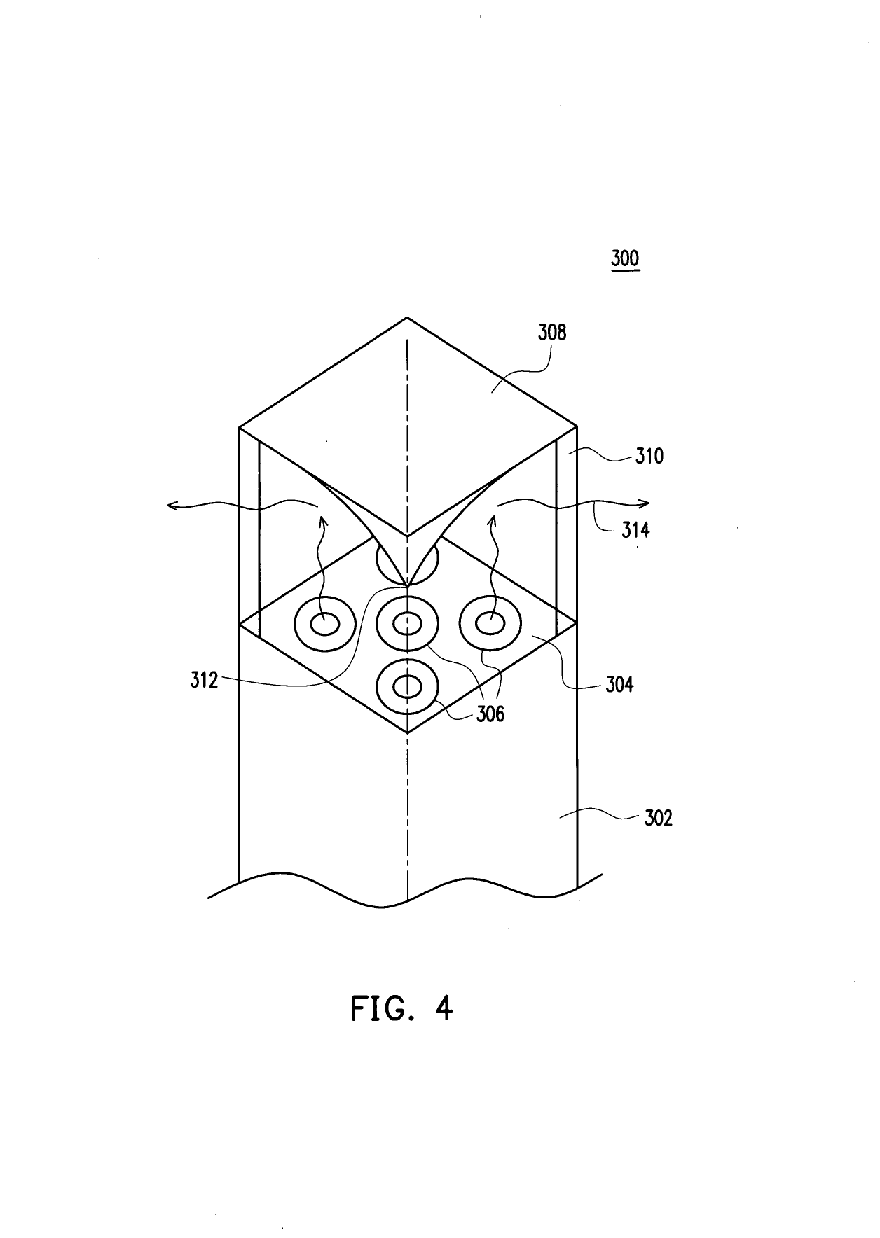

FIG. 4 is a perspective view showing a stereo speaker according to a third embodiment of the present invention. As shown in FIG. 4, the stereo speaker 300 is mainly constructed from a speaker 302 and a sonic reflector 308. The profile of the speaker 302 is shaped like a pillar with a diamond cross-section that is center-symmetric. The speaker 302 has a sound output opening 304 and the cross-section of the sound output opening 304 is shaped like a center-symmetric diamond. Multiple vibrating plates 306 are center-symmetrically allocated at the sound output opening 304. The sonic reflector 308 has a tapered shape with a diamond cross-section that corresponds to the cross-section of the sound output opening 304. The tip 312 of the sonic reflector 304 points towards the center of the sound output opening 304 of the speaker 302. The material of the sonic reflector 308 is metal, for example. The sonic reflector 308 has a curved surface. The sonic waves 314 can be reflected by the sonic reflector 308 in the direction substantially perpendicular to the direction in which the sonic waves 314 are generated from the speaker 302. The reflected sonic waves 314 are circularly scattered from the stereo speaker 300. Therefore, no matter where a user is, the user can hear the sound created from the stereo speaker 300 under a good condition. The sonic reflector 308 is allocated over the sound output opening 304 by a frame 310 such that the sound output opening 304 is spaced from the sonic reflector 308 in a determined distance in merit for reflecting the sonic waves 314.

The stereo speaker in accordance with the present invention can circularly scatter sonic waves. Therefore, the speakers can be easily installed and a wrap-around effect can be readily created.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A stereo speaker comprising:
two speakers each having a sound output opening, the sound output openings allocated face to face; and
a sonic reflection unit positioned between the speakers, the sonic reflection unit reflecting sonic waves created by the speakers in a direction substantially perpendicular to a direction in which the sonic waves are generated from the speakers, thereby the reflected sonic waves circularly scattered from the stereo speaker.

2. The stereo speaker according to claim 1, wherein the sonic reflection unit includes two sonic reflectors, each of the sonic reflectors has a tapered shape with a cross-section that corresponds to the cross-section of the sound output openings, and the tips of the sonic reflectors point in an opposite direction and towards a center of the sound output openings of the speakers, respectively.

3. The stereo speaker according to claim 1, wherein the sonic reflection unit is made of metal.

4. The stereo speaker according to claim 1, wherein a shape of the sound output opening is center-symmetric.

5. The stereo speaker according to claim 1, wherein a profile of the speaker is cylindrical.

6. The stereo speaker according to claim 1, further comprising a frame positioned between the speakers and connecting the speakers, the speakers spaced from each other in a determined distance by the frame and the sonic reflection unit fixed by the frame.

7. The stereo speaker according to claim 1, further comprising a pedestal connected with one of the speakers.

8. The stereo speaker according to claim 1, wherein each of the speakers includes at least one vibrating plate positioned at the sound output openings.

9. A stereo speaker comprising:
a speaker having a sound output opening; and
a sonic reflector positioned at the sound output opening, the sonic reflector reflecting sonic waves created by the speaker in a direction substantially perpendicular to a direction in which the sonic waves are generated from the speaker, thereby the reflected sonic waves circularly scattered from the stereo speaker.

10. The stereo speaker according to claim 9, wherein the sonic reflector has a tapered shape with a cross-section that corresponds to a cross-section of the sound output opening and a tip of the sonic reflector points towards a center of the sound output opening of the speaker.

11. The stereo speaker according to claim 9, wherein the sonic reflector is made of metal.

12. The stereo speaker according to claim 9, wherein a shape of the sound output opening is center-symmetric.

13. The stereo speaker according to claim 9, wherein a profile of the speaker is cylindrical.

14. The stereo speaker according to claim 9, further comprising a frame connecting the speaker and the sonic reflector, the frame spacing the sound output opening from the sonic reflector in a determined distance.

15. The stereo speaker according to claim 9, further comprising a pedestal connected with the speaker.

16. The stereo speaker according to claim 9, wherein the speaker includes at least one vibrating plate positioned at the sound output opening.

17. A stereo speaker comprising:
at least one speaker having a sound output opening, a shape of the sound output opening being center-symmetric; and
a sonic reflector positioned at the sound output opening, the sonic reflector having a tapered shape with a cross-section that corresponds to the cross-section of the sound output opening, and a tip of the sonic reflector pointing towards a center of the sound output opening of the speaker.

18. The stereo speaker according to claim 17, wherein the sonic reflector is made of metal.

19. The stereo speaker according to claim 17, further comprising a frame connecting the speaker and the sonic reflector, the frame spacing the sound output opening from the sonic reflector in a determined distance.
